(19) United States
(12) Patent Application Publication
(10) Pub. No.: US 2009/0003979 A1
(43) Pub. Date: Jan. 1, 2009

(54) TECHNIQUES FOR HANDLING SUBSTRATES

(75) Inventors: Dale K. Stone, Lynnfield, MA (US); Lyudmila Stone, Lynnfield, MA (US); Julian G. Blake, Gloucester, MA (US); Suneethi Gudapati, Windham, NH (US)

Correspondence Address: HUNTON & WILLIAMS LLP/VARIAN SEMICONDUCTOR,;EQUIPMENT ASSOCIATES, INC., INTELLECTUAL PROPERTY DEPARTMENT, 1900 K STREET, N.W., SUITE 1200, WASHINGTON, DC, 20006-1109, US

(73) Assignee: Varian Semiconductor Equipment Associates, Inc., Gloucester, MA (US)

(21) Appl. No.: 11/770,805

(22) Filed: Jun. 29, 2007

(51) Int. Cl. H01L 21/683

(52) U.S. Cl. 414/217.1; 414/805

(57) ABSTRACT

Techniques for handling substrates are disclosed. In one particular exemplary embodiment, the techniques may be realized as a substrate support. The substrate support may comprise a mounting portion. The substrate support may also comprise a wall extending from the mounting portion, wherein the wall may form a generally enclosed area and may have a contact surface at a distal end.

### FIELD OF THE DISCLOSURE

The present disclosure relates generally to semiconductor manufacturing and, more particularly, to techniques for handling substrates.

### BACKGROUND OF THE DISCLOSURE

Modern semiconductor manufacturing has created a need for automated handling of substrates during various steps of a manufacturing process. Responsive to this need, a number of machines have developed automatic or robotic arms to transport substrates. A typical robotic arm may have an end effector that comprises a substrate handler. The substrate handler may have substrate supports to carry the substrates. The throughput of the whole semiconductor industry has been enhanced by employing such automatic substrate handling.

Most existing methods of substrate handling suffer from substrate slipping and inherent deficiencies to control backside particle contamination. Substrate slipping is an issue well known in the art for automatic substrate handling. In substrate handlers that rely on gravity to hold substrates during operating, friction between the substrates and the contact surfaces of substrate supports prevents the substrates from moving laterally. Typically, to set the substrates into motion or stop movement of the substrates, there is a sudden change of momentum (e.g., a shock). Substrates may slip if the friction is not strong enough to hold the substrates in position to sustain the shock. Increasing contact surface area of the substrate supports may help control slipping of substrates but may lead to more backside particle contamination.

Backside particle contamination is an emerging concern as semiconductor device sizes become smaller and integration density increases. Particle contamination on the backside of substrates has become a serious issue in advanced microelectronics manufacturing for several reasons. One reason is that particles on the backside of substrates can cause cross contamination and electrical contact failures in interconnect structures. A second reason is changes in substrate planarity associated with such contamination. Specifically, particles present on the backside of the substrate can impact control over the critical dimension (CD) in lithographic processes by causing substrate warpage. The depth of focus in sub-half micron lithography is approximately ±0.5 μm, and factors such as field image curvature, circuit topography, substrate flatness and auto-focus errors reduce the usable focus margin. Therefore, ensuring the planarity of substrates during the lithographic process becomes more critical in obtaining tight CD control.

Most existing methods of substrate handling do not cope well with backside particle contamination. For example, one commonly used substrate handler uses a plurality of rubber pads as substrate supports. The rubber pads may be made of material of Kalrez, Silicone, or Perlast. The size of a contact area of a rubber pad may be dictated by the friction needed to hold the substrate. Thus, to prevent slipping of substrates, each rubber pad may have to have a certain size of contact area in order to have a good grip of the substrates. However, the flat contact surface area of a rubber pad is a source of backside particle contamination. Dust particles may collect on the rubber pads. Then, when the rubber pads make contact with the backs of the substrates, the backs of substrates may be contaminated by the dust particles.

Another type of substrate handler uses an O-ring as a substrate support to contact the backs of substrates. The O-ring typically has a certain diameter that enables it to hold a substrate of a certain size. The O-ring also has a nearly flat surface to collect dust and contaminate the backs of the substrates.

In view of the foregoing, it may be understood that there are significant problems and shortcomings associated with existing methods of substrate handling.

### SUMMARY OF THE DISCLOSURE

Techniques for handling substrates are disclosed. In one particular exemplary embodiment, the techniques may be realized as a substrate support. The substrate support may comprise a mounting portion. The substrate support may also comprise a wall extending from the mounting portion, wherein the wall may form a generally enclosed area and may have a contact surface at a distal end.

In accordance with other aspects of this particular exemplary embodiment, the wall may form a circle. The mounting portion and the wall may form a cylindrical shape. The mounting portion may have a rounded protrusion on a cylindrical surface. The protrusion may comprise an embedded component. The embedded component may be a metallic ring or a plurality of metallic bands. The substrate support may have a length in the range of, for example, between about 0.080 and 1.010 inch and a diameter in the range of, for example, between about 0.185 and 0.220 inch.

In accordance with further aspects of this particular exemplary embodiment, the contact surface of the wall may be a semi-toroidal rim. The semi-toroidal rim may have a round cross section, and the round cross section may comprise a half-circle with a radius in the range of between about 0.003 and 0.008 inch.

In accordance with additional aspects of this particular exemplary embodiment, the mounting portion may be a rectangular block.

In accordance with still other aspects of this particular exemplary embodiment, the mounting portion may have an opening at a distal end to accommodate a screw.

In accordance with still further aspects of this particular exemplary embodiment, the mounting portion may have a groove on a surface thereof to facilitate mounting of the substrate support.

In accordance with still additional aspects of this particular exemplary embodiment, the wall may be made of polymer material. The polymer material may be Polyurethane. And the Polyurethane may have a hardness of range between about Shore A 50 to Shore A 70.

In accordance with yet other aspects of this particular exemplary embodiment, the wall may have a plurality of discontinuous wall sections.

In accordance with yet further aspects of this particular exemplary embodiment, the wall may have an oval shape.

In accordance with yet additional aspects of this particular exemplary embodiment, the contact surface may have a cross section that is a tip of a triangular shaped wedge.

In another particular exemplary embodiment, the techniques may be realized as a substrate handler. The substrate handler may comprise an arm. The substrate handler may further comprise a plurality of substrate supports removably mounted to the arm. Each substrate support may comprise a mounting portion. Each substrate support may further comprise a wall extending from the mounting portion, wherein the wall forms a generally enclosed area and has a contact surface at a distal end.

In accordance with other aspects of this particular exemplary embodiment, the arm may have a plurality of cavities that the plurality of substrate supports are mounted therein. The cavities may be dovetail shaped holes.

In another particular exemplary embodiment, the techniques may be realized as a method. The method may comprise positioning a substrate handler underneath a substrate. The substrate handler may comprise an arm. The substrate handler may further comprise a plurality of substrate supports removably mounted to the arm. Each substrate support may comprise a mounting portion. Each substrate support may further comprise a wall extending from the mounting portion, wherein the wall may form a generally enclosed area and may have a contact surface at a distal. The method may also comprise moving the substrate handler upward to lift the substrate by the plurality of substrate supports. The method may further comprise transporting the substrate to a destination position. The method may additionally comprise depositing the substrate at the destination position.

The present disclosure will now be described in more detail with reference to exemplary embodiments thereof as shown in the accompanying drawings. While the present disclosure is described below with reference to exemplary embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIG. 1 shows a perspective view of a substrate handler in accordance with an embodiment of the present disclosure.

FIG. 2 shows a perspective view of a substrate support in accordance with an embodiment of the present disclosure.

FIG. 3 shows a cross-sectional view of the substrate support of FIG. 2 along line 3-3 in accordance with an embodiment of the present disclosure.

FIGS. 4A and 4B show two cross-sectional views of the substrate support of FIG. 2 along line 4-4 in accordance with an embodiment of the present disclosure.

FIG. 5 shows a sectional elevation of the substrate handler in accordance with an embodiment of the present disclosure.

FIG. 6 shows a perspective view of a substrate support in accordance with an embodiment of the present disclosure.

FIG. 7 shows a cross-sectional view of the substrate support of FIG. 6 along line 7-7 in accordance with an embodiment of the present disclosure.

FIG. 8 shows a sectional elevation of a substrate handler in accordance with an alternative embodiment of the present disclosure.

FIG. 9 shows a sectional elevation of a substrate handler in accordance with an alternative embodiment of the present disclosure.

FIG. 10 shows a flow diagram illustrating an exemplary method for substrate handling in accordance with an embodiment of the present disclosure.

### DETAILED DESCRIPTION OF EXEMPLARY EMBODIMENTS

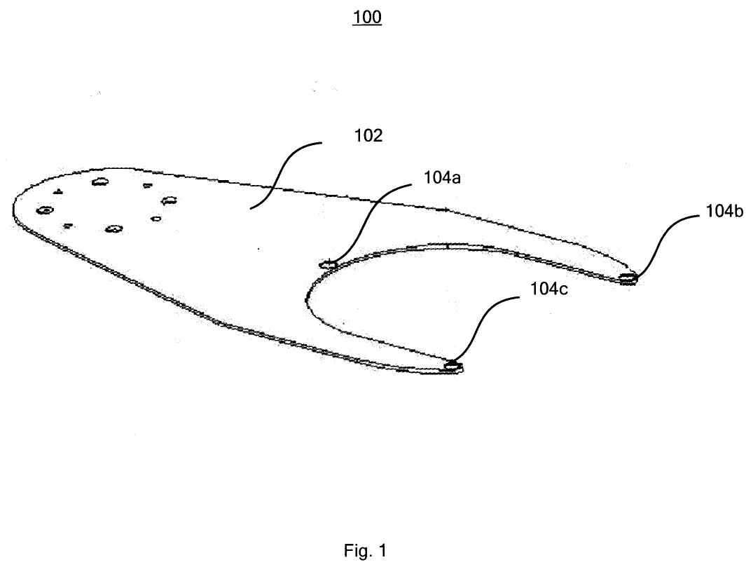

Referring to FIG. 1, there is shown a perspective view of an exemplary substrate handler 100 in accordance with an embodiment of the present disclosure. The substrate handler 100 may comprise an arm 102 and three substrate supports 104a, 104b and 104c. The substrate handler 100 may travel to a position underneath a substrate and move upward to pick up the substrate by the three substrate supports 104a, 104b and 104c. That is, the back of the substrate will make contact with the three substrate supports 104a, 104b and 104c and may be supported by the three substrate supports 104a, 104b and 104c. The substrate handler 100 relies on gravity to operate. That is, gravity pushes the substrate down on upper contact surfaces of substrate supports 104a, 104b and 104c. Friction between the back of the substrate and the upper contact surfaces of the substrate supports 104a, 104b and 104c provides a force that allows the substrate to move with the substrate handler 100.

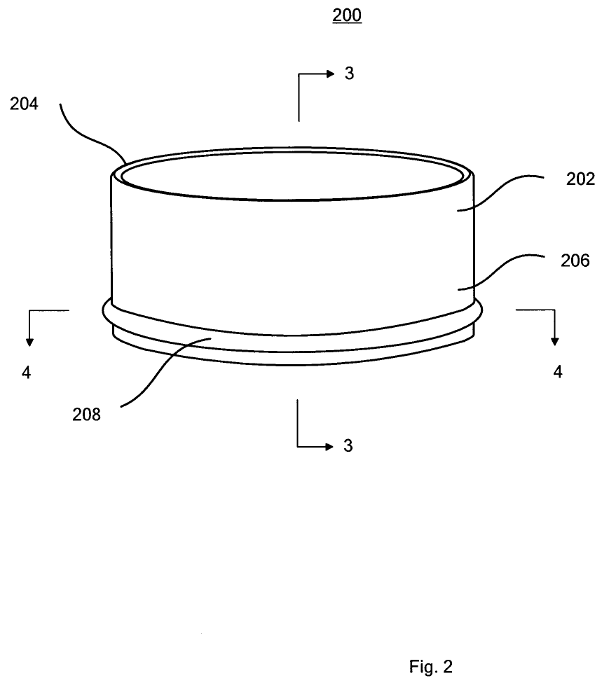

Referring to FIG. 2, there is shown a perspective view of an exemplary substrate support 200 in accordance with an embodiment of the present disclosure. The substrate support 200 has a cylindrical shape. At a first distal end portion 202, the substrate support has a rim 204. At a second distal end portion 206, there is a bulge 208 protruding from the cylindrical surface. The exemplary embodiment of the substrate support 200 may be made of one polymer material, such as, for example, Polyurethane, Silicone, Kalrez, Perlast. In another exemplary embodiment, the first distal end portion 202 may be made of one material (e.g., Polyurethane) and the second distal end portion 206 may be made of a different material (e.g., Metal).

The substrate support according to the present disclosure is not limited to a cylindrical shape. For example, the substrate support according to the present disclosure may have a geometrical shape different from the cylindrical shape as shown in FIG. 2. Further, the first distal end portion 202 and the second distal end portion 206 may have separate geometrical shapes. The different geometrical shapes are described later in the present disclosure.

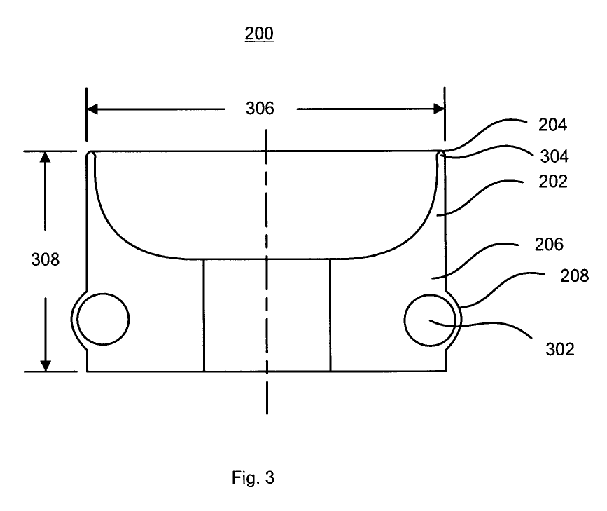

Referring to FIG. 3, there is shown a cross-sectional view of the substrate support 200 along line 3-3 of FIG. 2 in accordance with an embodiment of the present disclosure. The first distal end portion 202 of the substrate support 200 may be a wall extending from the second distal end portion 206. The extended wall shape may add flexibility to the rim 204. That is, the wall may tilt under force. Therefore, when the substrate support 200 carries a substrate, any change of momentum by the substrate handler (e.g., start moving or stop moving) may be cushioned before transferring the force to the carried substrate. In this regard, the first distal end portion 202 may perform shock absorption.

Tilting of the first distal end portion 202 reduces shock to the carried substrate and reduces substrate slipping. The hardness of the material may determine how well the wall may tilt under force. As described previously, the substrate support 200 may be made of Polyurethane. The hardness of Polyurethane may be in a range between Shore A 50 to Shore A 70 (Shore A is a standard hardness scale known in the art). In the exemplary embodiment of substrate support 200, the Polyurethane has a hardness of Shore A 62.

In the exemplary embodiment of substrate support 200, the rim 204 of the first distal end portion has a semi-toroidal shape. That is, the cross-section curve of the rim 204 is a half circle 304. The radius of the half circle 304 may be a value in a range, for example, between 0.003 to 0.007 inch. In the exemplary embodiment substrate support 200, the radius of the half circle 304 is 0.005 inch.

Also, the semi-toroidal shape of the rim 204 forms a circle with a diameter 306. The diameter 306 may be determined by how the substrate support may be used. The exemplary embodiment substrate support 200 may be used as one of a plurality of substrate supports in a substrate handler as shown in FIG. 1. When a plurality of substrate supports are used, the diameter 306 may be in a range, for example, between 0.185 to 0.215 inch. In an exemplary embodiment of substrate support 200, the diameter 306 is 0.2 inch. However, an exemplary embodiment of substrate support in accordance with the present disclosure may be used alone on a substrate handler, e.g. an orienter of an ion implanter has only one substrate support. When used alone to support substrates, the embodiments of substrate support in accordance with the present disclosure may have various values of diameters.

The shape and dimension of the rim 204 reduces backside particle contamination. First, because of the shape and dimension of the rim 204, dust may not be easily collected on the tip (e.g., contact surface) of the half circle 304. Second, because the contact surface between the substrate support 200 and the substrate has a small area, dust particles typically do not attach to the back of the substrate during operation (e.g., carrying substrates). And third, even when dust particles do collect on the contact surface of the rim 204, contacting the backside of the substrate typically results in the substrate brushing the dust particles off the rim 204. Thus, the rim 204 provides an in situ cleaning mechanism. That is, rim 204 has a capability to clean itself during operation.

The substrate support 200 also has a length 308 from the rim 204 to the end of the second distal end portion 206. The length 308 may be in the range, for example, between 0.80 to 1.10 inch. In the exemplary embodiment substrate support 200, the length 308 is 0.95 inch. Also shown in FIG. 3, there is a component 302 embedded inside the bulge 208. The component 302 may provide a fastening mechanism to fasten the substrate support 200 to a substrate handler, e.g., substrate handler 100. The component 302 may also provide a strengthening mechanism. That is, the component 302 may keep the polymer material in its cylindrical shape. Therefore, the component 302 is made of a hard material, such as, but not limited to, metal. In the exemplary embodiment substrate support 200, the component 302 has a round cross section. In other embodiments in accordance to the present disclosure, the component 302 may have different shapes of cross section, such as, for example, a rectangular shape. The component 302 may be a ring of a single piece or multiple pieces. In an alternative embodiment, the component 302 may not be embedded inside the bulge 208, but rather just attached to the cylindrical surface to form the bulge 208.

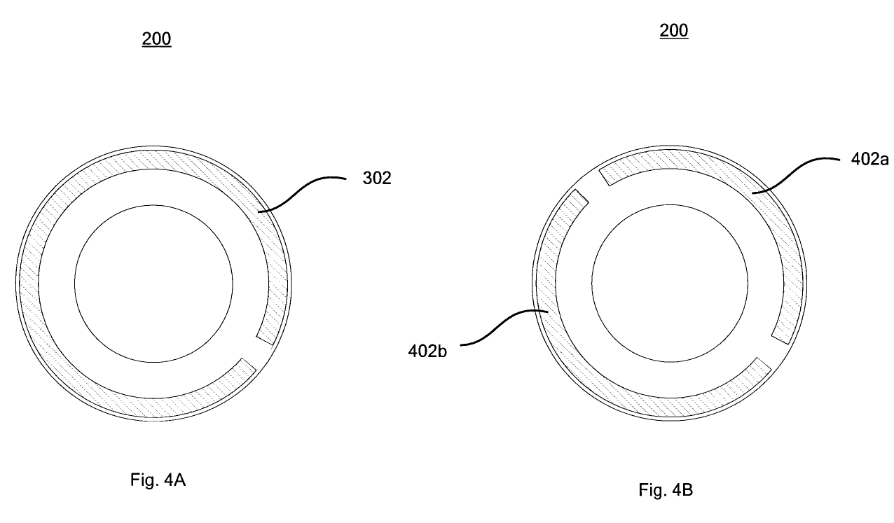

Referring to FIGS. 4A and 4B, there are shown cross-sectional views of the substrate support 200 along line 4-4 of FIG. 2 in accordance with an embodiment of the present disclosure. In FIG. 4A, the component 302 is a C-shaped ring (e.g., a C-ring). The C-ring may be made of metal or other hard material. A hard C-ring may provide strength to the substrate support 200. In FIG. 4B, there is shown two pieces of embedded component 402a and 402b. The two pieces of embedded component 402a and 402b may be two metallic bands and may provide similar functionality as the single C-ring component 302 shown in FIG. 4A.

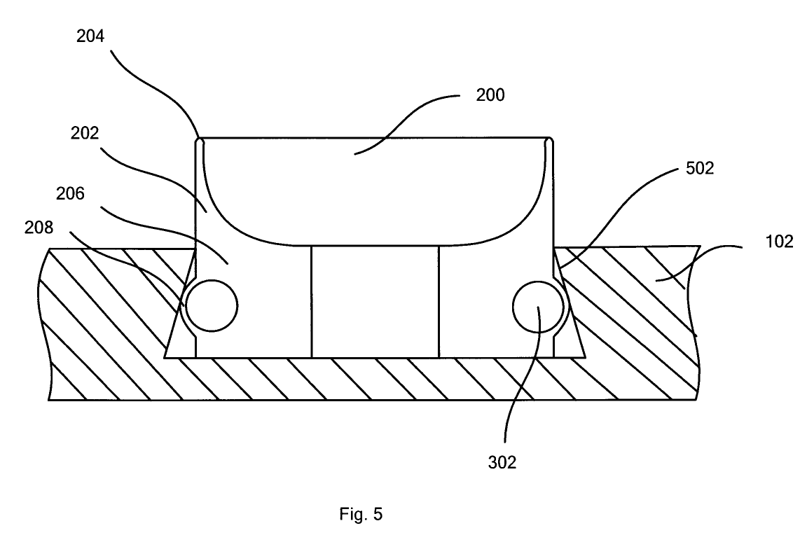

Referring to FIG. 5, there is shown a sectional elevation of the substrate handler 100 in accordance with an embodiment of the present disclosure. A substrate support 200 may be mounted on the substrate handler 100 by a cavity 502 in the arm 102. The cavity 502 may have a shape that accommodates the substrate support 100. In the exemplary embodiment as shown, the cavity 502 may be a round hole. The hole is not shown as a through hole, that is, the hole only has one opening in the arm 102. The radius of the opening may have a smaller value than the radius of the bottom of the hole. The cross-sectional view of the cavity 502 is in a “dovetail” shape. The second distal end portion 206 secures the substrate support 100 in the arm 102. The bulge 208 fits in the cavity 502 and fastens the substrate support 100 to the arm 102.

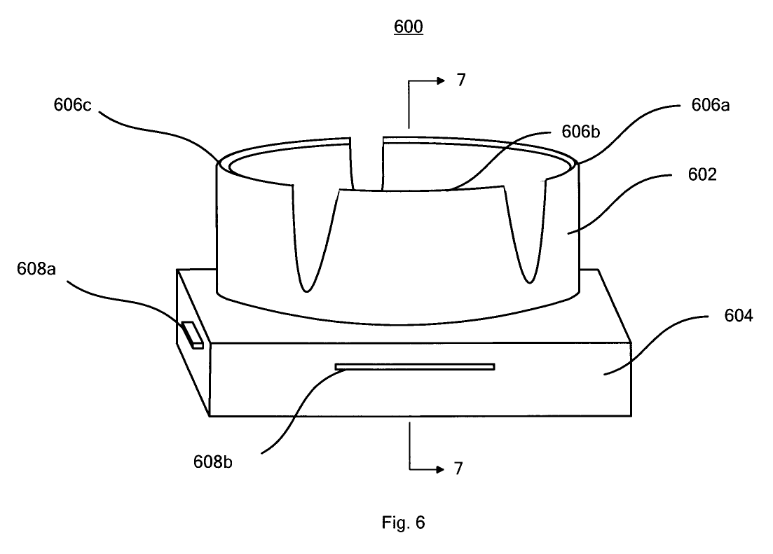

Referring to FIG. 6, there is shown a perspective view of an alternate substrate support 600 in accordance with an embodiment of the present disclosure. As previously described, a substrate support according to the present disclosure may have other shapes. FIG. 6 illustrates an exemplary substrate support 600 having an alternate shape in accordance with an embodiment of the present disclosure. The substrate support 600 has a rectangular block mounting portion 604. A wall 602 extends from the mounting portion 604. The wall 602 is discontinuous with three gaps therein. The rim of the wall 602 is divided by the three gaps into three sections: rim 606a, 606b and 606c. In the exemplary embodiment shown in FIG. 6, the wall 602 may have an oval shape instead of a circle shape. In addition, the rim sections 606a, 606b, and 606c may have tips that have cross sections that look like a triangular wedge instead of a semi-toroidal curve. Except the tip, the shape of wall 602 and rim sections 606a, 606b, 606c of substrate support 600 are similar to the shape of wall 202 and rim 204 of substrate support 200. The features described for wall 202 and rim 204 of substrate support 200 are similarly applicable. The wall 602 may be made, for example, of Polyurethane of hardness Shore A 50 to Shore A 70, as described previously. The mounting portion 604 may be made, for example, with a second material, such as, but not limited to, Kalrez, or metal. In an exemplary embodiment of substrate support 600, the wall 602 may be made of Polyurethane with a hardness of Shore A 62, and the mounting portion 604 may be made of Kalrez.

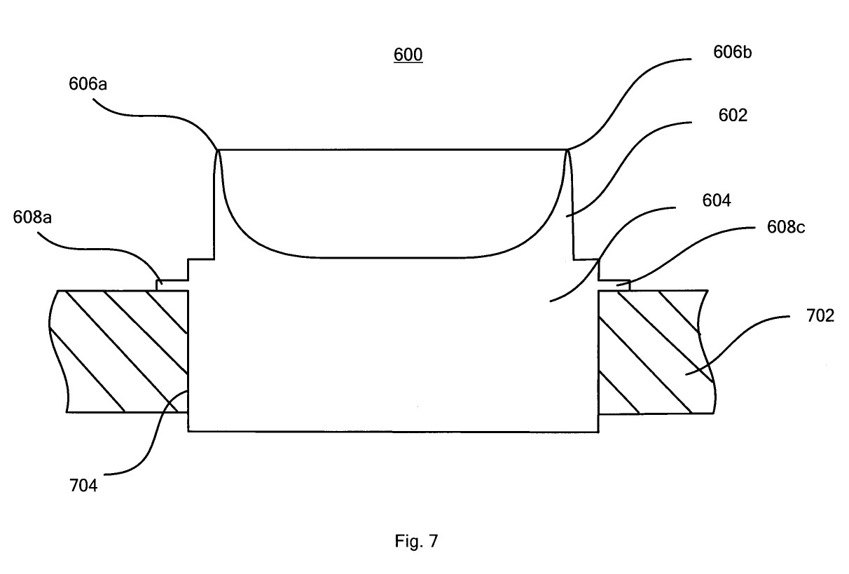

The substrate support 600 has four rectangular protrusions to position itself when placed on an arm. Of the four rectangular protrusions, two (608a, 608b), are shown in FIG. 6 and a third (608c) is shown in FIG. 7.

Referring to FIG. 7, there is shown a cross-sectional view of the substrate support 600 along line 7-7 of FIG. 6 in accordance with an embodiment of the present disclosure. As shown in FIG. 7, the substrate support 600 may be mounted on a through rectangular hole 704 on an arm 702. The substrate support 600 may be secured by the rectangular shape of the mounting portion 604 fitting in the rectangular hole 704 on the arm 702. The mounting portion 604 is positioned by the rectangular protrusions 608a and 608c as shown.

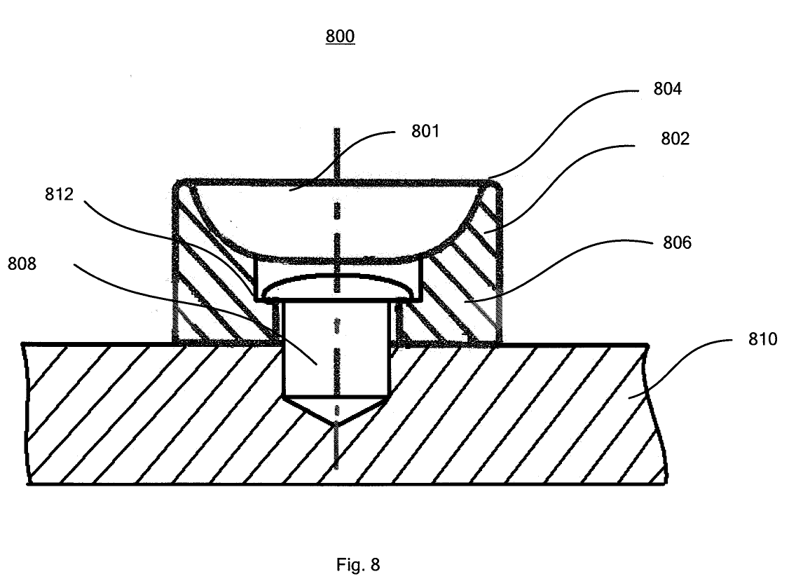

Referring to FIG. 8, there is shown a sectional elevation of an substrate handler 800 in accordance with an alternative embodiment of the present disclosure. As shown in FIG. 8, the exemplary substrate handler 800 has a substrate support 801 with a wall 802 extending from a mounting portion 806. The wall 802 has a rim 804 which may form a circle. The mounting portion 806 has an opening 812 at its distal end. A tip of a screw 808 may pass through the opening 812 and fasten the mounting portion 806. The substrate support 801 is mounted on an arm 810 by the screw 808.

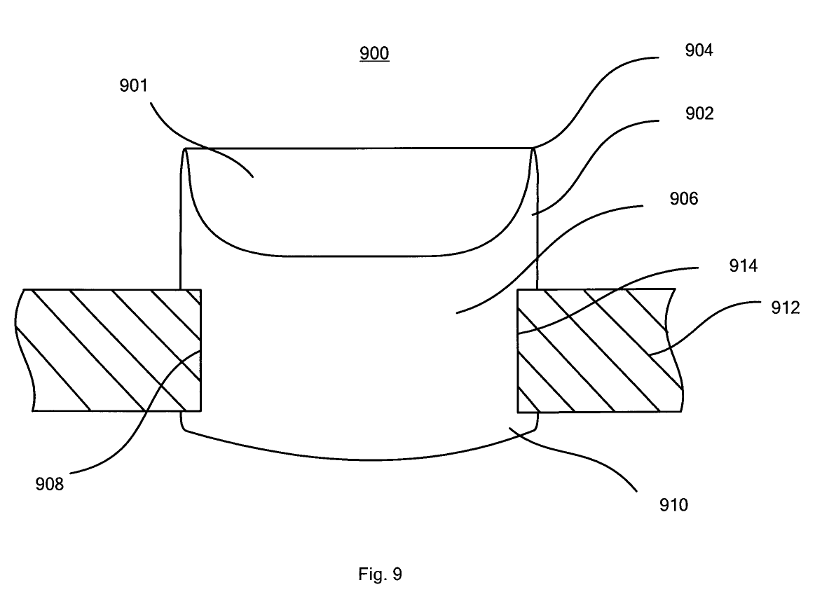

Referring to FIG. 9, there is shown a sectional elevation of an substrate handler 900 in accordance with an alternative embodiment of the present disclosure. An shown in FIG. 9, the exemplary substrate handler 900 has a substrate support 901 with a wall 902 extending from a mounting portion 906. The wall 902 has a rim 904 which may form a circle. The substrate support 901 may have a groove 908 on a cylindrical surface of the mounting portion 906. The groove 908 may form a annular slot on the cylindrical surface of the mounting portion 906. The substrate support 901 may be mounted to an arm 912 by pressing the mounting portion 906 of the substrate support 901 through a hole 914 on the arm 912. The mounting portion 906 may be made of soft or flexible material (e.g., Silicone, or Polyurethane) so that a distal end 910 of the mounting portion 906 may be pressed through the hole 914.

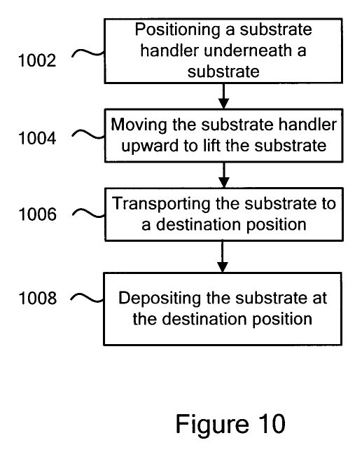

Referring to FIG. 10, there is shown a flow diagram illustrating an exemplary method for substrate handling in accordance with an embodiment of the present disclosure. In step 1002, a substrate handler may be positioned underneath a substrate. The substrate handler may be an exemplary substrate handler 100 for example.

In step 1004, the substrate handler may be moved upwards to lift the substrate. For example, the substrate handler 100 may lift the substrate by three substrate supports 104a, 104b, and 104c.

In step 1006, the substrate is transported to a destination position. For example, the substrate handler 100 may be an end effector that loads/unloads substrates to a position for processing. Friction between the back of the substrate and the three substrate supports 104a, 104b, and 104c provides a lateral force on the substrate.

In step 1008, the substrate is deposited at the destination position. For example, once reached the destination position, the substrate handler 100 may move downward, thereby leaving the substrate to substrate supports on a processing platform or substrate supports of a loading rack.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A substrate support comprising:
a mounting portion; and
a wall extending from the mounting portion, wherein the wall forms a generally enclosed area and has a contact surface at a distal end.

2. The substrate support according to claim 1, wherein the wall forms a circle.

3. The substrate support according to claim 2, wherein the mounting portion and the wall form a cylindrical shape.

4. The substrate support according to claim 3, wherein the mounting portion has a rounded protrusion on a cylindrical surface, the protrusion comprising an embedded component.

5. The substrate support according to claim 4, wherein the embedded component is a metallic C-ring.

6. The substrate support according to claim 1, wherein the contact surface of the wall is a semi-toroidal rim.

7. The substrate support according to claim 6, wherein semi-toroidal rim has a round cross section, and the round cross section comprises a half-circle with a radius in the range of between about 0.003 and 0.008 inch.

8. The substrate support according to claim 3, wherein the substrate support has a length in the range of between about 0.080 and 1.010 inch and a diameter in the range of between about 0.185 and 0.220 inch.

9. The substrate support according to claim 1, wherein the mounting portion is a rectangular block.

10. The substrate support according to claim 1, wherein the mounting portion has an opening at a distal end to accommodate a screw.

11. The substrate support according to claim 1, wherein the mounting portion has a groove on a surface thereof to facilitate mounting of the substrate support.

12. The substrate support according to claim 1, wherein the wall is made of polymer material.

13. The substrate support according to claim 12, wherein the polymer material is Polyurethane.

14. The substrate support according to claim 13, wherein the Polyurethane has a hardness of range between about Shore A 50 to Shore A 70.

15. The substrate support according to claim 1, wherein the wall has a plurality of discontinuous wall sections.

16. The substrate support according to claim 1, wherein the wall has an oval shape.

17. The substrate support according to claim 1, wherein the contact surface has a cross section that is a tip of a triangular shaped wedge.

18. The substrate support according to claim 4, wherein the embedded component is a plurality of metallic bands.

19. A substrate handler comprising:
an arm; and
a plurality of substrate supports removably mounted to the arm, each substrate support comprising:
a mounting portion; and
a wall extending from the mounting portion, wherein the wall forms a generally enclosed area and has a contact surface at a distal end.

20. The substrate handler according to claim 19, wherein the arm has a plurality of cavities, wherein the plurality of substrate supports are mounted in the plurality of cavities.

21. The substrate handler according to claim 20, wherein the cavities are dovetail shaped holes.

22. A method comprising:
positioning a substrate handler underneath a substrate, the substrate handler comprising:
an arm; and
a plurality of substrate supports removably mounted to the arm, each substrate support comprising:
a mounting portion; and
a wall extending from the mounting portion,
wherein the wall forms a generally enclosed area and has a contact surface at a distal end;
moving the substrate handler upward to lift the substrate by the plurality of substrate supports;
transporting the substrate to a destination position; and
depositing the substrate at the destination position.
